(19) United States
(12) Patent Application Publication
(10) Pub. No.: US 2015/0061730 A1
(43) Pub. Date: Mar. 5, 2015

(54) LATCH AND OPERATION METHOD THEREOF AND COMPARATOR

(71) Applicant: Industrial Technology Research Institute, Hsinchu (TW)

(72) Inventors: Chia-Ming Tsai, Hsinchu City (TW); Bo-Jyun Kuo, Hsinchu City (TW); Bo-Wei Chen, Miaoli County (TW)

(73) Assignee: Industrial Technology Research Institute, Hsinchu (TW)

(21) Appl. No.: 14/097,267

(22) Filed: Dec. 5, 2013

(30) Foreign Application Priority Data
Sep. 4, 2013 (TW) 102131815

(51) Int. Cl. H03K 3/356

(52) U.S. Cl. CPC H03K 3/356034
USPC 327/57; 327/215

(57) ABSTRACT

A latch, an operation method of the latch, and a comparator using the latch are disclosed. The latch includes first and second cross-coupled pairs and first and second transistor pairs. First terminals of the first and second current paths of the first cross-coupled pair are respectively coupled to first terminals of the first and second transistors of the first transistor pair. First terminals of the third and fourth current paths of the second cross-coupled pair are respectively coupled to first terminals of the third and fourth transistors of the second transistor pair. Control terminals of the third and fourth transistors are respectively coupled to the first and second current paths. Control terminals of the first and second transistors are respectively coupled to the third and fourth current paths.

### CROSS-REFERENCE TO RELATED APPLICATION

This application claims the priority benefit of Taiwan application serial no. 102131815, filed on Sep. 4, 2013. The entirety of the above-mentioned patent application is hereby incorporated by reference herein and made a part of this specification.

### TECHNICAL FIELD

The disclosure relates to a latch and an operation method thereof and a comparator using the latch.

### BACKGROUND

Circuit design of low supply voltage is a hot research topic on low power applications. In order to achieve low power consumption, a common method is to decrease a supply voltage of a circuit. However, as the supply voltage is decreased, a general latch structure may encounter many problems, for example, the operation speed thereof is slowed down, and the delay time is obviously increased, etc.

FIG. 1 is a circuit block diagram of a latch 200, which is stacked by two cross-coupled pair circuits. During a process of signal transition, when a signal OUTP of the latch 200 shown in FIG. 1 is equal to a signal OUTN, the circuit is operated in a common mode. Now, a DC half-circuit model of the latch 200 of FIG. 1 can be simplified as a DC half-circuit. It is shown in FIG. 2. Under the common mode operation condition, and in case that an influence of a channel length modulation effect is not considered, it is also assumed that a characteristic of NMOS transistor is the same with that of PMOS transistor, in order to obtain the maximum transconductance for all of the NMOS transistors and the PMOS transistors to achieve a maximum signal gain. The both signals, i.e. OUTP and OUTN, on FIG. 2 have to be OUTP=OUTN=(Vdd−Vss)/2. In order to obtain a larger signal gain to improve a circuit operation speed of the latch 200, an overdrive voltage of the transistors must be enhanced. Operating at common mode, however, regarding a circuit structure of the latch 200, enhancement of the overdrive voltage cannot be achieved since maximum DC voltage operation conditions of the signals OUTP and OUTN both are (Vdd−Vss)/2.

### SUMMARY

The disclosure is directed to a latch including a first cross-coupled pair circuit, a first transistor pair circuit, a second transistor pair circuit, and a second cross-coupled pair circuit. The first cross-coupled pair circuit includes a first current path and a second current path, where a control terminal of the first current path is coupled to the second current path, and a control terminal of the second current path is coupled to the first current path. The second cross-coupled pair circuit includes a third current path and a fourth current path, where a control terminal of the third current path is coupled to the fourth current path, and a control terminal of the fourth current path is coupled to the third current path. The first transistor pair circuit includes a first transistor and a second transistor. A control terminal of the first transistor is coupled to the third current path, and a first terminal of the first transistor is coupled to a first terminal of the first current path. A control terminal of the second transistor is coupled to the fourth current path, and a first terminal of the second transistor is coupled to a first terminal of the second current path. The second transistor pair circuit includes a third transistor and a fourth transistor. A control terminal of the third transistor is coupled to the first current path, and a first terminal of the third transistor is coupled to a first terminal of the third current path. A control terminal of the fourth transistor is coupled to the second current path, and a first terminal of the fourth transistor is coupled to a first terminal of the fourth current path.

The disclosure provides an operation method of a latch including following steps. A first cross-coupled pair circuit including a first current path and a second current path is configured, where a control terminal of the first current path is coupled to the second current path, and a control terminal of the second current path is coupled to the first current path. A first transistor pair circuit including a first transistor and a second transistor is configured, where a first terminal of the first transistor is coupled to a first terminal of the first current path, and a first terminal of the second transistor is coupled to a first terminal of the second current path. A second transistor pair circuit including a third transistor and a fourth transistor is configured, where a control terminal of the third transistor is coupled to the first current path, and a control terminal of the fourth transistor is coupled to the second current path. A second cross-coupled pair circuit including a third current path and a fourth current path is configured, where a control terminal of the third current path is coupled to the fourth current path, and a control terminal of the fourth current path is coupled to the third current path, a first terminal of the third current path is coupled to a first terminal of the third transistor, a first terminal of the fourth current path is coupled to a first terminal of the fourth transistor, a control terminal of the first transistor is coupled to the third current path, and a control terminal of the second transistor is coupled to the fourth current path. In a signal transition phase, an input signal is injected into the first current path, the second current path, the third current path, or the fourth current path, meanwhile, the injected input signal would be amplified by the first cross-coupled pair circuit and the second cross-coupled pair circuit. In a stable phase, the first transistor pair circuit cuts off a static current of the first current path or the second current path, and the second transistor pair circuit cuts off a static current of the third current path or the fourth current path.

The disclosure provides a comparator including a first switch, a second switch, a control circuit, a first cross-coupled pair circuit, a first transistor pair circuit, a second transistor pair circuit, a second cross-coupled pair circuit, and a dynamic pre-amplifier circuit. The first cross-coupled pair circuit includes a first current path and a second current path, where a control terminal of the first current path is coupled to the second current path, and a control terminal of the second current path is coupled to the first current path. The second cross-coupled pair circuit includes a third current path and a fourth current path, where a control terminal of the third current path is coupled to the fourth current path, and a control terminal of the fourth current path is coupled to the third current path. The first transistor pair circuit includes a first transistor and a second transistor, where a first terminal of the first transistor is coupled to a first terminal of the first current path, and a first terminal of the second transistor is coupled to a first terminal of the second current path. The second transistor pair circuit includes a third transistor and a fourth transistor, where a control terminal of the third current path is coupled to the first current path of the first cross-coupled pair circuit, and a control terminal of the fourth transistor is coupled to the second current path of the first cross-coupled pair circuit. A first terminal of the third current path is coupled to a first terminal of the third transistor, a first terminal of the fourth current path is coupled to a first terminal of the fourth transistor, a control terminal of the first transistor is coupled to the third current path, and a control terminal of the second transistor is coupled to the fourth current path. A first terminal of the first switch is coupled to a second terminal of the first current path and a second terminal of the second current path. A second terminal of the first switch is coupled to a first power supply voltage. A first terminal of the second switch is coupled to a second terminal of the third current path and a second terminal of the fourth current path. A second terminal of the second switch is coupled to a second power supply voltage. The control circuit comprises a first control circuit, a second control circuit or a third control circuit. The dynamic pre-amplifier circuit performs a pre-amplifying operation according to a first input signal and a second input signal, and outputs a first internal signal a second internal signal to the control circuit. Wherein, the first control circuit of the control circuit comprises a third switch, a fourth switch, a fifth switch, a sixth switch and a seventh switch, a first terminal of the third switch coupled to the control terminal of the third transistor, a second terminal of the third switch coupled to a reference voltage, a first terminal of the fourth switch coupled to the control terminal of the fourth transistor, a second terminal of the fourth switch coupled to the reference voltage, a first terminal of the fifth switch coupled to the control terminal of the first transistor, a first terminal of the sixth switch coupled to the control terminal of the second transistor, a first terminal of the seventh switch coupled to a second terminal of the fifth switch and a second terminal of the sixth switch, a second terminal of the seventh switch coupled to the reference voltage, the dynamic pre-amplifier circuit outputs the first internal signal to the control terminal of the fourth switch and the control terminal of the fifth switch, and the dynamic pre-amplifier circuit outputs the second internal signal to the control terminal of the third switch and the control terminal of the sixth switch. Wherein, the second control circuit of the control circuit comprises a third switch and a fourth switch, a first terminal of the third switch coupled to the control terminal of the third transistor, a second terminal of the third switch coupled to a reference voltage, a first terminal of the fourth switch coupled to the control terminal of the fourth transistor, a second terminal of the fourth switch coupled to the reference voltage, the dynamic pre-amplifier circuit outputs the first internal signal to the control terminal of the fourth switch, and the dynamic pre-amplifier circuit outputs the second internal signal to the control terminal of the third switch. Wherein, the third control circuit of the control circuit comprises a fifth switch, a sixth switch and a seventh switch, a first terminal of the fifth switch coupled to the control terminal of the first transistor, a first terminal of the sixth switch coupled to the control terminal of the second transistor, a first terminal of the seventh switch coupled to a second terminal of the fifth switch and a second terminal of the sixth switch, a second terminal of the seventh switch coupled to the reference voltage, the dynamic pre-amplifier circuit outputs the first internal signal to the control terminal of the fifth switch, and the dynamic pre-amplifier circuit outputs the second internal signal to the control terminal of the sixth switch.

Several exemplary embodiments accompanied with figures are described in detail below to further describe the disclosure in details.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a circuit block diagram of a general latch circuit.

FIG. 2 is a schematic diagram of a DC half-circuit of the general latch circuit of FIG. 1 in a common mode operation condition.

FIG. 3 is a circuit block schematic diagram of a latch according to an embodiment of the disclosure.

FIG. 4 is a circuit schematic diagram of the latch of FIG. 3 according to an embodiment of the disclosure.

FIG. 5 is a schematic diagram of a DC half-circuit of the latch circuit of FIG. 4 in a common mode operation condition.

FIG. 6 is a circuit schematic diagram of a cross-coupled pair circuit 110 of FIG. 3 according to another embodiment of the disclosure.

FIG. 7 is a circuit schematic diagram of a cross-coupled pair circuit 140 of FIG. 3 according to another embodiment of the disclosure.

FIG. 8 is a circuit schematic diagram of a first transistor pair circuit 120 of FIG. 3 according to another embodiment of the disclosure.

FIG. 9 is a circuit schematic diagram of the first transistor pair circuit 120 of FIG. 3 according to still another embodiment of the disclosure.

FIG. 10 is a circuit schematic diagram of the first transistor pair circuit 120 of FIG. 3 according to yet another embodiment of the disclosure.

FIG. 11 is a circuit schematic diagram of a second transistor pair circuit 130 of FIG. 3 according to another embodiment of the disclosure.

FIG. 12 is a circuit schematic diagram of the second transistor pair circuit 130 of FIG. 3 according to still another embodiment of the disclosure.

FIG. 13 is a circuit schematic diagram of the second transistor pair circuit 130 of FIG. 3 according to yet another embodiment of the disclosure.

FIG. 14 is a circuit block schematic diagram of a latch having a clock signal control function according to another embodiment of the disclosure.

FIG. 15 is a circuit block schematic diagram of a comparator having a signal comparison function according to another embodiment of the disclosure.

FIG. 16 is a schematic diagram of an output signal readout circuit of the comparator of FIG. 15 according to an embodiment of the disclosure.

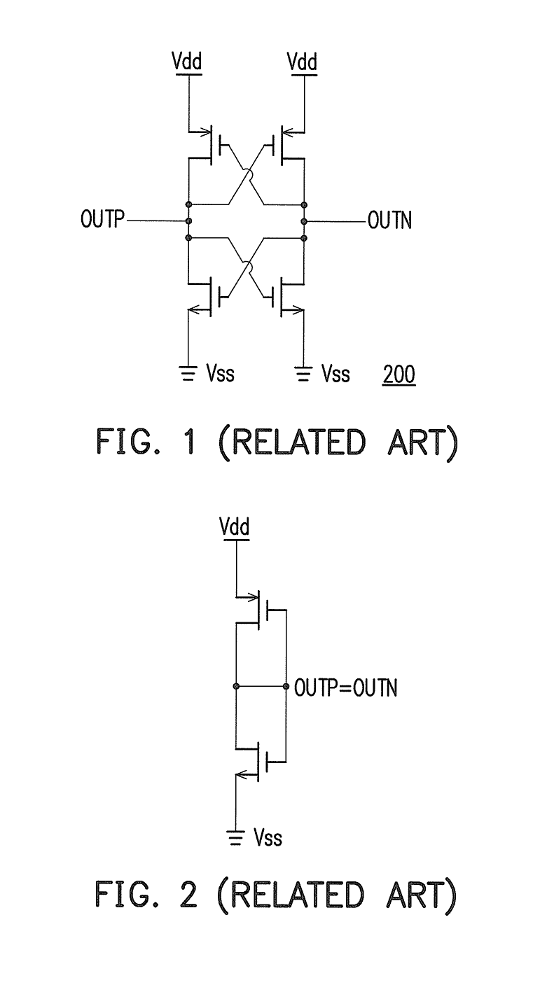

### DETAILED DESCRIPTION OF DISCLOSED EMBODIMENTS

A term “couple” used in the full text of the disclosure (including the claims) refers to any direct and indirect connections. For example, if a first device is described to be coupled to a second device, it is interpreted as that the first device is directly coupled to the second device, or the first device is indirectly coupled to the second device through other devices or connection means. Moreover, wherever possible, components/members/steps using the same referential numbers in the drawings and description refer to the same or like parts. Components/members/steps using the same referential numbers or using the same terms in different embodiments may cross-refer related descriptions.

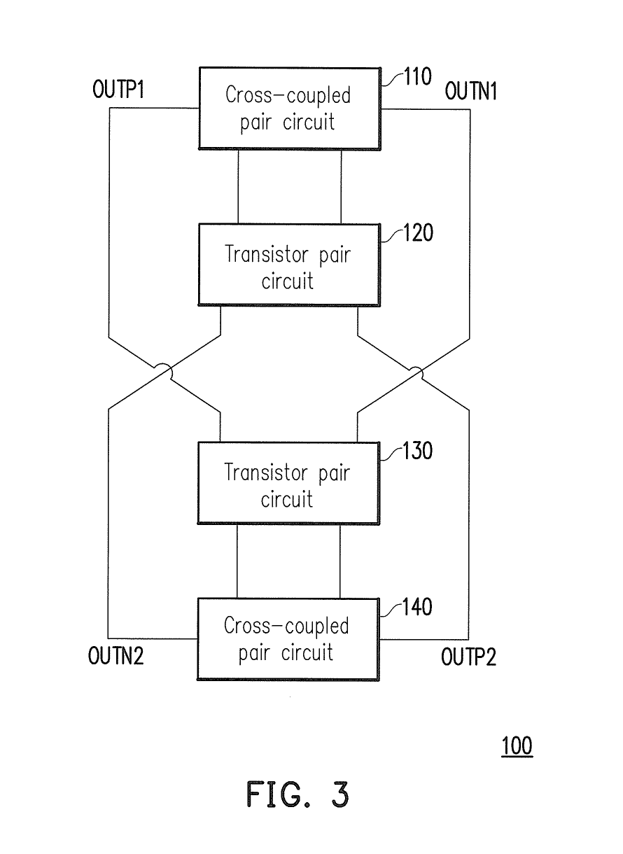

FIG. 3 is a circuit block schematic diagram of a latch 100 according to an embodiment of the disclosure. The latch 100 includes a first cross-coupled pair circuit 110, a first transistor pair circuit 120, a second transistor pair circuit 130 and a second cross-coupled pair circuit 140. The first cross-coupled pair circuit 110 includes a first current path and a second current path, where a control terminal of the first current path is coupled to the second current path, and a control terminal of the second current path is coupled to the first current path. For example, the control terminal of the first current path is coupled to a first terminal of the second current path, and the control terminal of the second current path is coupled to a first terminal of the first current path. Other implementation details of the first cross-coupled pair circuit 110 are described later. The second cross-coupled pair circuit 140 includes a third current path and a fourth current path, where a control terminal of the third current path is coupled to the fourth current path, and a control terminal of the fourth current path is coupled to the third current path. For example, the control terminal of the third current path is coupled to a first terminal of the fourth current path, and the control terminal of the fourth current path is coupled to a first terminal of the third current path. Other implementation details of the second cross-coupled pair circuit 140 are described later.

The first transistor pair circuit 120 includes a first transistor and a second transistor. A first terminal of the first transistor in the first transistor pair circuit 120 is coupled to the first terminal of the first current path in the first cross-coupled pair circuit 110, and a control terminal of the first transistor in the first transistor pair circuit 120 is coupled to the first terminal of the third current path in the second cross-coupled pair circuit 140. A first terminal of the second transistor in the first transistor pair circuit 120 is coupled to the first terminal of the second current path in the first cross-coupled pair circuit 110, and a control terminal of the second transistor in the first transistor pair circuit 120 is coupled to the first terminal of the fourth current path in the second cross-coupled pair circuit 140. A second terminal of the first current path and a second terminal of the second current path in the first cross-coupled pair circuit 110 are coupled to a first power supply voltage, and a second terminal of the first transistor and a second terminal of the second transistor in the first transistor pair circuit 120 are coupled to a second power supply voltage. The first power supply voltage and the second power supply voltage can be a system supply voltage Vdd, a ground voltage Vss or other constant voltages. For example, the first power supply voltage and the second power supply voltage can be respectively the system supply voltage Vdd and the ground voltage Vss.

The second transistor pair circuit 130 includes a third transistor and a fourth transistor. A first terminal of the third transistor in the second transistor pair circuit 130 is coupled to the first terminal of the third current path in the second cross-coupled pair circuit 140, and a control terminal of the third transistor in the second transistor pair circuit 130 is coupled to the first terminal of the first current path in the first cross-coupled pair circuit 110. A first terminal of the fourth transistor in the second transistor pair circuit 130 is coupled to the first terminal of the fourth current path in the second cross-coupled pair circuit 140, and a control terminal of the fourth transistor in the second transistor pair circuit 130 is coupled to the first terminal of the second current path in the first cross-coupled pair circuit 110. A second terminal of the third current path and a second terminal of the fourth current path in the second cross-coupled pair circuit 140 are coupled to the second power supply voltage, and a second terminal of the third transistor and a second terminal of the fourth transistor in the second transistor pair circuit 130 are coupled to the first power supply voltage.

When the latch is operated in a common mode operation condition, i.e. DC voltage conditions of signals OUTP1 and OUTN1 are the same, and DC voltage conditions of signals OUTP2 and OUTN2 are also the same, the first cross-coupled pair circuit 110 and the first transistor pair circuit 120 can be regarded as a high gain amplifier, and the second cross-coupled pair circuit 130 and the second transistor pair circuit 140 can be regarded as another high gain amplifier. When the input signals to be latched are respectively injected to the first current path and the second current path in the first cross-coupled pair circuit 110, and/or respectively injected to the third current path and the fourth current path in the second cross-coupled pair circuit 140, during the signal transition phase, the injected input signals are amplified through the two high gain amplifiers. Meanwhile, a difference of the injected signals can be further amplified through a positive feedback path formed through a signal coupling relation of the latch 100 of FIG. 3, so as to provide a higher signal amplification gain to achieve a high speed operation.

Since the first transistor pair circuit 120 is controlled by the second cross-coupled pair circuit 140, in a stable phase, means that the signal transition completed, the first transistor pair circuit 120 cuts off a static current of the first current path and/or the second current path in the first cross-coupled pair circuit 110. Similarly, since the second transistor pair circuit 130 is controlled by the first cross-coupled pair circuit 110, in the stable phase, the second transistor pair circuit 130 cuts off a static current of the third current path and/or the fourth current path in the second cross-coupled pair circuit 140. Therefore, when the latch 100 is in a stable state, static power consumption of the latch 100 is decreased.

Implementations of the first cross-coupled pair circuit 110, the first transistor pair circuit 120, the second transistor pair circuit 130 and the second cross-coupled pair circuit 140 is not limited by the disclosure. For example, the transistors in the first cross-coupled pair circuit 110 and the second transistor pair circuit 130 are first conductive type channels, and the transistors in the first transistor pair circuit 120 and the second cross-coupled pair circuit 140 are second conductive type channels. If the first conductive type is one of an N-type and a P-type, the second conductive type is another one of the N-type and the P-type. For example, if the first transistor and the second transistor in the first transistor pair circuit 120 are P-channel metal oxide semiconductor (PMOS) transistors. In other words, the third transistor and the fourth transistor in the second transistor pair circuit 130 are N-channel metal oxide semiconductor (NMOS) transistors.

In summary, the embodiment of FIG. 3 discloses an operation method of the latch 110, which includes following steps. The first cross-coupled pair circuit 110 including the first current path and the second current path is configured, where the control terminal of the first current path is coupled to the second current path, and the control terminal of the second current path is coupled to the first current path. The first transistor pair circuit 120 including the first transistor and the second transistor is configured, where the first terminal of the first transistor is coupled to the first terminal of the first current path of the first cross-coupled pair circuit 110, and the first terminal of the second transistor is coupled to the first terminal of the second current path of the first cross-coupled pair circuit 110. The second transistor pair circuit 130 including the third transistor and the fourth transistor is configured, where the control terminal of the third transistor is coupled to the first current path of the first cross-coupled pair circuit 110, and the control terminal of the fourth transistor is coupled to the second current path of the first cross-coupled pair circuit 110. The second cross-coupled pair circuit 140 including the third current path and the fourth current path is configured, where the control terminal of the third current path is coupled to the fourth current path, and the control terminal of the fourth current path is coupled to the third current path, the first terminal of the third current path is coupled to the first terminal of the third transistor of the second transistor pair circuit 130, the first terminal of the fourth current path is coupled to the first terminal of the fourth transistor of the second transistor pair circuit 130, the control terminal of the first transistor of the first transistor pair circuit 120 is coupled to the third current path of the second cross-coupled pair circuit 140, and the control terminal of the second transistor of the first transistor pair circuit 120 is coupled to the fourth current path of the second cross-coupled pair circuit 140. In a signal transition phase, the input signal is injected into the first current path, the second current path, the third current path or the fourth current path, the first cross-coupled pair circuit 110 and the second cross-coupled pair circuit 140 amplify the injected input signal. In a stable phase, means that the signal transition completed, the first transistor pair circuit 120 cuts off the static current of the first current path or the second current path in the first cross-coupled pair circuit 110, and the second transistor pair circuit 130 cuts off the static current of the third current path or the fourth current path in the second cross-coupled pair circuit 140.

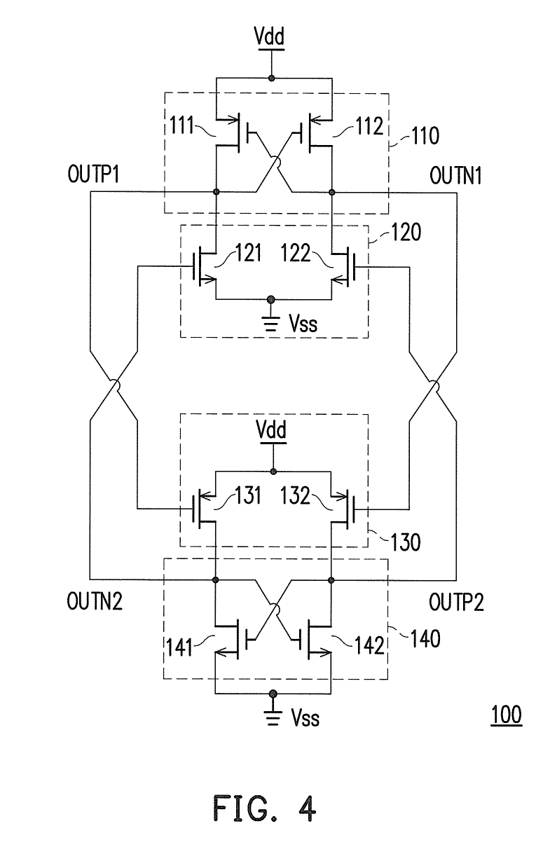

FIG. 4 is a circuit schematic diagram of the latch 110 of FIG. 3 according to an embodiment of the disclosure. The first cross-coupled pair circuit 110 includes a first transistor 111 and a second transistor 112. The first transistor 111 is disposed in the first current path of the first cross-coupled pair circuit 110, where a first terminal (for example, a drain) of the first transistor 111 serves as the first terminal of the first current path and is coupled to the first transistor pair circuit 120, and a control terminal (for example, a gate) of the first transistor 111 serves as the control terminal of the first current path. The second transistor 112 is disposed in the second current path of the first cross-coupled pair circuit 110, where a first terminal (for example, a drain) of the second transistor 112 serves as the first terminal of the second current path and is coupled to the control terminal of the first transistor 111 and the first transistor pair circuit 120, and a control terminal (for example, a gate) of the second transistor 112 serves as the control terminal of the second current path and is coupled to the first terminal of the first transistor 111. A second terminal (for example, a source, which is also the second terminal of the first current path) of the first transistor 111 and a second terminal (for example, a source, which is also the second terminal of the second current path) of the second transistor 112 are coupled to the first power supply voltage (for example, the system supply voltage Vdd). In the present embodiment, the first transistor 111 and the second transistor 112 can be PMOS transistors, though in other embodiments, implementations of the first transistor 111 and the second transistor 112 are not limited thereto.

The first transistor pair circuit 120 includes a transistor 121 and a transistor 122. A first terminal (for example, a drain) of the transistor 121 is coupled to the first terminal of the first current path in the first cross-coupled pair circuit 110, and a control terminal (for example, a gate) of the transistor 121 is coupled to the first terminal of the third current path in the second cross-coupled pair circuit 140. A first terminal (for example, a drain) of the transistor 122 is coupled to the first terminal of the second current path in the first cross-coupled pair circuit 110, and a control terminal (for example, a gate) of the transistor 122 is coupled to the first terminal of the fourth current path in the second cross-coupled pair circuit 140. A second terminal (for example, a source) of the transistor 121 and a second terminal (for example, a source) of the transistor 122 are coupled to the second power supply voltage (for example, the ground voltage Vss). In the present embodiment, the transistor 121 and the transistor 122 can be NMOS transistors, though in other embodiments, implementations of the transistor 121 and the transistor 122 are not limited thereto.

The second cross-coupled pair circuit 140 includes a transistor 141 and a transistor 142. The transistor 141 is disposed in the third current path of the second cross-coupled pair circuit 140, where a first terminal (for example, a drain) of the transistor 141 serves as the first terminal of the third current path and is coupled to the second transistor pair circuit 130, and a control terminal (for example, a gate) of the transistor 141 serves as the control terminal of the third current path. The transistor 142 is disposed in the fourth current path of the second cross-coupled pair circuit 140, where a first terminal (for example, a drain) of the transistor 142 serves as the first terminal of the fourth current path and is coupled to the control terminal of the transistor 141 and the second transistor pair circuit 130, and a control terminal (for example, a gate) of the transistor 142 serves as the control terminal of the fourth current path and is coupled to the first terminal of the transistor 141. A second terminal (for example, a source, which is also the second terminal of the third current path) of the transistor 141 and a second terminal (for example, a source, which is also the second terminal of the fourth current path) of the transistor 142 are coupled to the second power supply voltage (for example, the ground voltage Vss). In the present embodiment, the transistor 141 and the transistor 142 can be NMOS transistors, though in other embodiments, implementations of the transistor 141 and the transistor 142 are not limited thereto.

The second transistor pair circuit 130 includes a third transistor 131 and a fourth transistor 132. A first terminal (for example, a drain) of the third transistor 131 is coupled to the first terminal of the third current path in the second cross-coupled pair circuit 140, and a control terminal (for example, a gate) of the third transistor 131 is coupled to the first terminal of the first current path in the first cross-coupled pair circuit 110. A first terminal (for example, a drain) of the fourth transistor 132 is coupled to the first terminal of the fourth current path in the second cross-coupled pair circuit 140, and a control terminal (for example, a gate) of the fourth transistor 132 is coupled to the first terminal of the second current path in the first cross-coupled pair circuit 110. A second terminal (for example, a source) of the third transistor 131 and a second terminal (for example, a source) of the fourth transistor 132 are coupled to the first power supply voltage (for example, the system supply voltage Vdd). In the present embodiment, the third transistor 131 and the fourth transistor 132 can be PMOS transistors, though in other embodiments, implementations of the third transistor 131 and the fourth transistor 132 are not limited thereto.

Regarding the high gain amplifier formed by the first cross-coupled pair circuit 110 and the first transistor pair circuit 120, the first terminals of the first current path and the second current path can serve as a signal input terminal and/or a signal output terminal of the latch 100. Similarly, regarding the high gain amplifier formed by the second cross-coupled pair circuit 140 and the second transistor pair circuit 130, the first terminals of the third current path and the fourth current path can serve as the signal input terminal and/or the signal output terminal of the latch 100. For example, in an embodiment, the first terminals of the first current path and the second current path in the first cross-coupled pair circuit 110 are selected to serve as the signal input terminal and the signal output terminal of the latch 110, or the first terminals of the third current path and the fourth current path in the second cross-coupled pair circuit 140 are selected to serve as the signal input terminal and the signal output terminal of the latch 110. For another example, in another embodiment, the first terminals of the first current path and the second current path in the first cross-coupled pair circuit 110 are selected to serve as the signal input terminals of the latch 110, and the first terminals of the third current path and the fourth current path in the second cross-coupled pair circuit 140 are selected to serve as the signal output terminals of the latch 110. Alternatively, the first terminals of the first current path and the second current path in the first cross-coupled pair circuit 110 are selected to serve as the signal output terminals of the latch 110, and the first terminals of the third current path and the fourth current path in the second cross-coupled pair circuit 140 are selected to serve as the signal input terminals of the latch 110. For another example, in other embodiments, the first terminals of the first current path and the second current path in the first cross-coupled pair circuit 110 and the first terminals of the third current path and the fourth current path in the second cross-coupled pair circuit 140 are selected to serve as the signal input terminals and the signal output terminals of the latch 110.

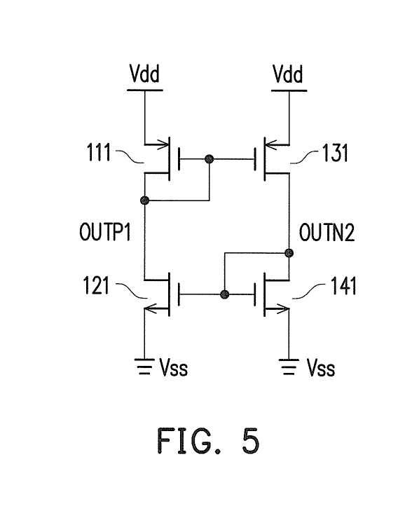

Referring to FIG. 4, when the signal OUTP1=the signal OUTN1 and the signal OUTP2=the signal OUTN2, the circuit shown in FIG. 4 is operated in the common mode operation condition. FIG. 5 is a schematic diagram of a DC half-circuit of the latch circuit of FIG. 4 in the common mode operation condition. Referring to FIG. 5, it is assumed that the latch 100 is operated in the common mode operation condition, i.e. the signal OUTP1=the signal OUTN1 and the signal OUTP2=the signal OUTN2, and an influence of a channel length modulation effect is not considered, and it is assumed that a characteristic of the NMOS transistor is the same with that of the PMOS transistor. Now, a DC voltage operation condition of the signal OUTP 1 (=the signal OUTN1) can be design between Vss and (Vdd−Vss)/2. Similarly, the DC voltage operation condition of the signal OUTP2 (=the signal OUTN2) can be design between (Vdd−Vss)/2 and Vdd. Therefore, the PMOS transistors and NMOS transistors in internal of the latch 100 shown in FIG. 4 may obtain larger overdrive voltage, so as to further enhance a signal gain and an operation speed of the latch 100. Particularly, while the supply voltage (Vdd−Vss) decreased, enhancement of the operation speed is more obvious.

Referring to FIG. 4, under the common mode operation condition, voltages of the signal OUTN2 and the signal OUTP2 are the same, and voltages of the signal OUTN1 and the signal OUTP1 are the same. It is assumed that the input signal to be latched is simultaneously injected to the cross-coupled pair circuits 110 and 140, where the high potential input signal is assumed to be injected to the signal OUTN2 and the signal OUTN1, and the low potential input signal is assumed to be injected to the signal OUTP2 and the signal OUTP1, such that the positive feedback path composed of the transistors 141 and 142 starts to latch the signal OUTN2 and the signal OUTP2, and the voltage of the signal OUTN2 should be able to pull high and the voltage of the signal OUTP2 pull low. Therefore, the transistor 141 gradually enters a cut off region, and the transistor 142 gradually enters a triode region. Meanwhile, the signal OUTN2 and the signal OUTP2 also control the operations of the N-type transistors 121 and 122 of the first transistor pair circuit 120, such that the transistor 122 gradually enters the cut off region, and the transistor 121 gradually enters the triode region.

Meanwhile, in another positive feedback path composed of the N-type transistors 111 and 112, the input signal to be latched and injected to the signal OUTN1 and the signal OUTP1 starts to latch the signal OUTN1 and the signal OUTP1, such that the voltage of the signal OUTN1 should be able to pull high and the voltage of the signal OUTP1 pull low. Therefore, the first transistor 111 gradually enters the cut off region, and the second transistor 112 gradually enters the triode region. Meanwhile, the signal OUTN1 and the signal OUTP1 also control the transistors 131 and 132, such that the fourth transistor 132 gradually enters the cut off region, and the third transistor 131 gradually enters the triode region. Therefore, besides that the cross-coupled pair circuit of each stage forms a complete positive feedback path, another positive feedback path can be formed through the signal OUTP 1, the signal OUTN 1, the signal OUTP2, and the signal OUTN2 between the first cross-coupled pair circuit 110 composed of the P-type transistors and the second cross-coupled pair circuit 140 composed of the N-type transistors, so as to further enhance the signal gain to achieve a high speed latching operation.

It should be noticed that implementation of the latch 100 of FIG. 3 is not limited to the embodiment of FIG. 4. For example, in other embodiments, the transistors 111, 112, 131 and 132 are N-type transistors, and the transistors 121, 122, 141 and 142 are P-type transistors, the first power supply voltage can be the ground voltage Vss, and the second power supply voltage can be the system supply voltage Vdd.

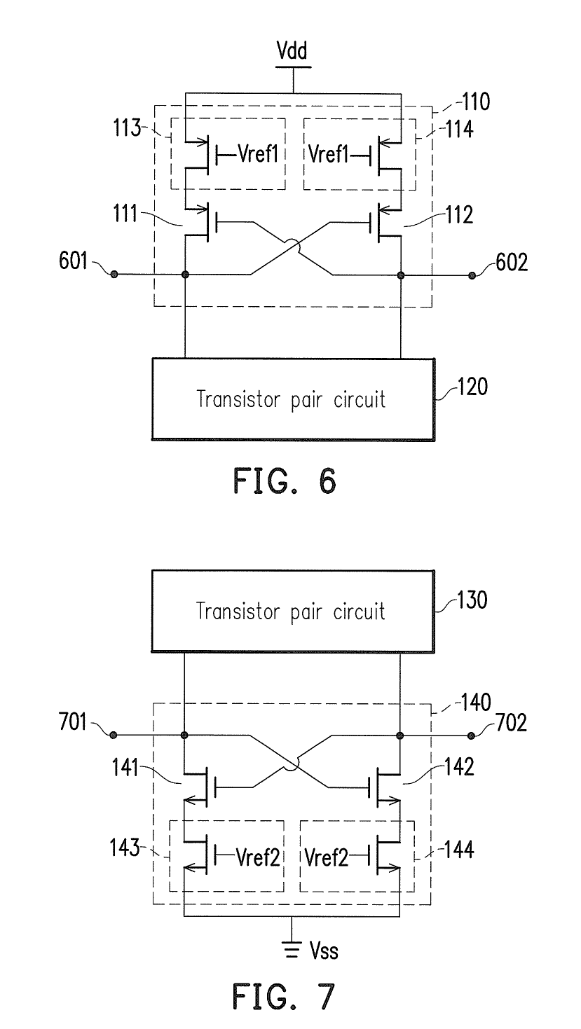

FIG. 6 is a circuit schematic diagram of the first cross-coupled pair circuit 110 of FIG. 3 according to another embodiment of the disclosure. The embodiment of FIG. 6 can be deduced by referring to related description of FIG. 3 or FIG. 4. Referring to FIG. 6, a node 601 can be coupled to the control terminal of the third transistor in the second transistor pair circuit 130 of FIG. 3, and a node 602 can be coupled to the control terminal of the fourth transistor in the second transistor pair circuit 130 of FIG. 3. In the present embodiment, the first cross-coupled pair circuit 110 includes the first transistor 111, the second transistor 112, an impedance 113, and an impedance 114. A first terminal of the impedance 113 is coupled to the second terminal (for example, the source) of the first transistor 111. A second terminal of the impedance 113 is indirectly or directly coupled to the first power supply voltage (for example, the system supply voltage Vdd). A first terminal of the impedance 114 is coupled to the second terminal (for example, the source) of the second transistor 112. A second terminal of the impedance 114 is indirectly or directly coupled to the first power supply voltage.

The impedance 113 and the impedance 114 can be transistors or other devices capable of providing impendence. For example, in the embodiment of FIG. 6, PMOS transistors are used to implement the impedance 113 and the impedance 114. A reference voltage V_{ref1} (for example, the ground voltage Vss, or other bias voltages) is supplied to gates of the PMOS transistors in the impedance 113 and the impedance 114.

FIG. 7 is a circuit schematic diagram of the second cross-coupled pair circuit 140 of FIG. 3 according to another embodiment of the disclosure. The embodiment of FIG. 7 can be deduced by referring to related description of FIG. 3 or FIG. 4. Referring to FIG. 7, a node 701 can be coupled to the control terminal of the first transistor in the first transistor pair circuit 120 of FIG. 3, and a node 702 can be coupled to the control terminal of the second transistor in the first transistor pair circuit 120 of FIG. 3. In the present embodiment, the second cross-coupled pair circuit 140 includes the transistor 141, the transistor 142, an impedance 143, and an impedance 144. A first terminal of the impedance 143 is coupled to the second terminal (for example, the source) of the transistor 141. A second terminal of the impedance 143 is indirectly or directly coupled to the second power supply voltage (for example, the ground voltage Vss). A first terminal of the impedance 144 is coupled to the second terminal (for example, the source) of the transistor 142. A second terminal of the impedance 144 is indirectly or directly coupled to the second power supply voltage.

The impedance 143 and the impedance 144 can be transistors or other devices capable of providing impendence. For example, in the embodiment of FIG. 7, NMOS transistors are used to implement the impedance 143 and the impedance 144. A reference voltage V_{ref2} (for example, the system supply voltage Vdd, or other bias) is supplied to gates of the NMOS transistors in the impedance 143 and the impedance 144.

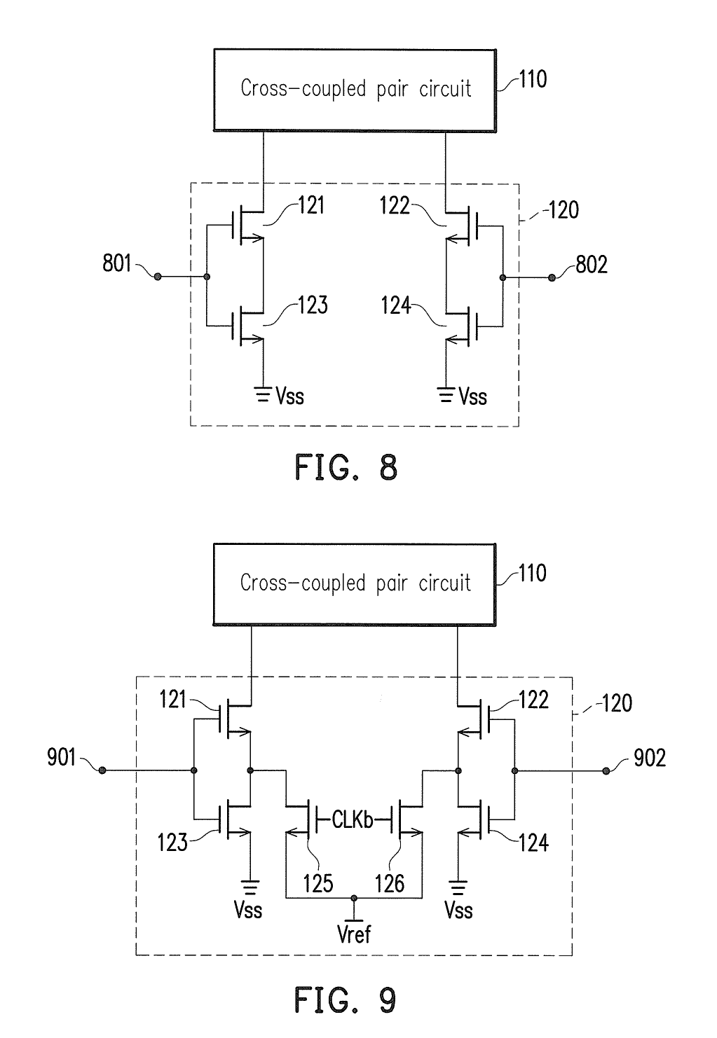

FIG. 8 is a circuit schematic diagram of the first transistor pair circuit 120 of FIG. 3 according to another embodiment of the disclosure. The embodiment of FIG. 8 can be deduced by referring to related description of FIG. 3 or FIG. 4. Referring to FIG. 8, a node 801 is coupled to the first terminal of the third current path in the second cross-coupled pair circuit 140, and a node 802 is coupled to the first terminal of the fourth current path in the second cross-coupled pair circuit 140. In the present embodiment, the first transistor pair circuit 120 includes the transistor 121, the transistor 122, a transistor 123 and a transistor 124. The first terminal (for example, the drain) of the transistor 121 is coupled to the first terminal of the first current path in the first cross-coupled pair circuit 110, and the control terminal (for example, the gate) of the transistor 121 is coupled to the first terminal of the third current path in the second cross-coupled pair circuit 140. A first terminal (for example, a drain) of the transistor 123 is coupled to the second terminal (for example, the source) of the transistor 121, a control terminal (for example, a gate) of the transistor 123 is coupled to the control terminal of the transistor 121, and a second terminal (for example, a source) of the transistor 123 is coupled to the second power supply voltage (for example, the ground voltage Vss). The first terminal (for example, the drain) of the transistor 122 is coupled to the first terminal of the second current path in the first cross-coupled pair circuit 110, and the control terminal (for example, the gate) of the transistor 122 is coupled to the first terminal of the fourth current path in the second cross-coupled pair circuit 140. A first terminal of the transistor 124 is coupled to the second terminal (for example, the source) of the transistor 122, a control terminal (for example, a gate) of the transistor 124 is coupled to the control terminal of the transistor 122, and a second terminal (for example, a source) of the transistor 124 is coupled to the second power supply voltage. In the present embodiment, the transistor 121, the transistor 122, the transistor 123 and the transistor 124 can be NMOS transistors. In other embodiments, implementations of the transistor 121, the transistor 122, the transistor 123 and the transistor 124 can be different.

FIG. 9 is a circuit schematic diagram of the first transistor pair circuit 120 of FIG. 3 according to still another embodiment of the disclosure. The embodiment of FIG. 9 can be deduced by referring to related description of FIG. 3 or FIG. 4. Different to the embodiment of FIG. 8, the first transistor pair circuit 120 of FIG. 9 further includes a switch 125 and a switch 126. Referring to FIG. 9, a node 901 is coupled to the first terminal of the third current path in the second cross-coupled pair circuit 140, and a node 902 is coupled to the first terminal of the fourth current path in the second cross-coupled pair circuit 140. A first terminal (for example, a drain) of the switch 125 is coupled to the second terminal (for example, the source) of the transistor 121, a control terminal of the switch 125 is coupled to a clock signal CLKb, and a second terminal (for example, a source) of the switch 125 is coupled to a reference voltage V_{ref} (for example, the ground voltage Vss or other bias voltages). A first terminal (for example, a drain) of the switch 126 is coupled to the second terminal (for example, the source) of the transistor 122, a control terminal of the switch 126 is coupled to the clock signal CLKb, and a second terminal (for example, a source) of the switch 126 is coupled to the reference voltage V_{ref}. When the latch 100 is operated in a reset phase, the switch 125 and the switch 126 are turned on, and voltages at the second terminals of the transistors 121 and 122 are reset to the reference voltage V_{ref}.

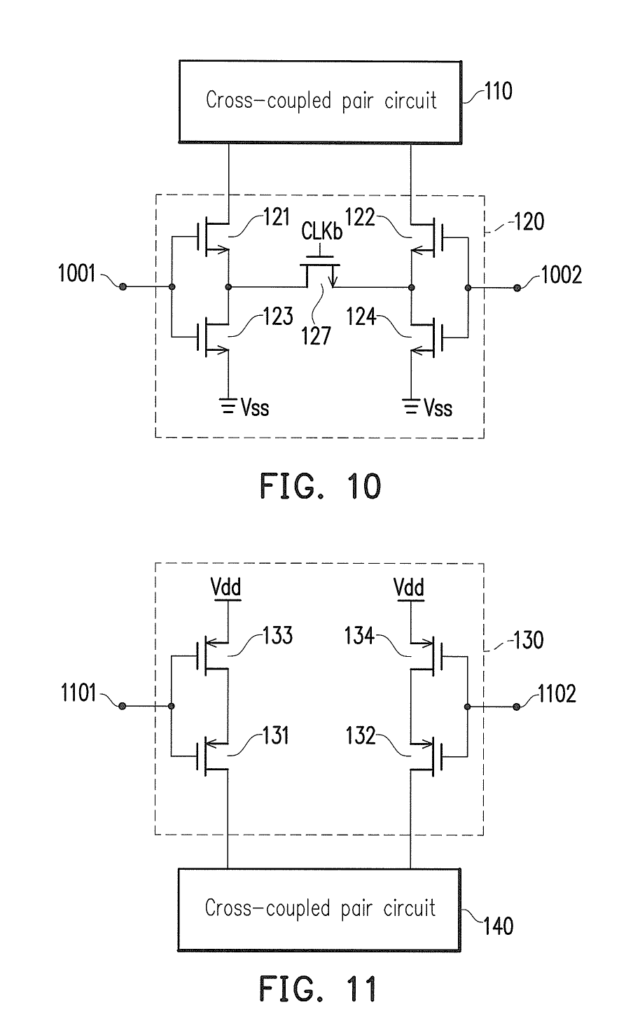

FIG. 10 is a circuit schematic diagram of the first transistor pair circuit 120 of FIG. 3 according to yet another embodiment of the disclosure. The embodiment of FIG. 10 can be deduced by referring to related description of FIG. 3 or FIG. 4. Different to the embodiment of FIG. 8, the first transistor pair circuit 120 of FIG. 10 further includes a switch 127. Referring to FIG. 10, a node 1001 is coupled to the first terminal of the third current path in the second cross-coupled pair circuit 140, and a node 1002 is coupled to the first terminal of the fourth current path in the second cross-coupled pair circuit 140. A first terminal (for example, a drain) of the switch 127 is coupled to the second terminal (for example, the source) of the transistor 121, a second terminal (for example, a source) of the switch 127 is coupled to the second terminal (for example, the source) of the transistor 122, and a control terminal of the switch 127 is coupled to the clock signal CLKb. When the latch 100 is operated in the reset phase, the switch 127 is turned on, and voltages at the second terminals of the transistors 121 and 122 are averaged.

FIG. 11 is a circuit schematic diagram of the second transistor pair circuit 130 of FIG. 3 according to another embodiment of the disclosure. The embodiment of FIG. 11 can be deduced by referring to related description of FIG. 3 or FIG. 4. Referring to FIG. 11, a node 1101 is coupled to the first terminal of the first current path in the first cross-coupled pair circuit 110, and a node 1102 is coupled to the first terminal of the second current path in the first cross-coupled pair circuit 110. In the present embodiment, the second transistor pair circuit 130 includes the third transistor 131, the fourth transistor 132, a transistor 133, and a transistor 134. The first terminal (for example, the drain) of the third transistor 131 is coupled to the first terminal of the third current path in the second cross-coupled pair circuit 140, and the control terminal (for example, the gate) of the third transistor 131 is coupled to the first terminal of the first current path in the first cross-coupled pair circuit 110. A first terminal (for example, a drain) of the transistor 133 is coupled to the second terminal (for example, the source) of the third transistor 131, a control terminal (for example, a gate) of the transistor 133 is coupled to the control terminal of the third transistor 131, and a second terminal (for example, a source) of the transistor 133 is coupled to the first power supply voltage (for example, the system supply voltage Vdd). The first terminal (for example, the drain) of the fourth transistor 132 is coupled to the first terminal of the fourth current path in the second cross-coupled pair circuit 140, and the control terminal (for example, the gate) of the fourth transistor 132 is coupled to the first terminal of the second current path in the first cross-coupled pair circuit 110. A first terminal (for example, a drain) of the transistor 134 is coupled to the second terminal (for example, the source) of the fourth transistor 132, a control terminal (for example, a gate) of the transistor 134 is coupled to the control terminal of the fourth transistor 132, and a second terminal (for example, a source) of the transistor 134 is coupled to the first power supply voltage. In the present embodiment, the third transistor 131, the fourth transistor 132, the transistor 133 and the transistor 134 can be PMOS transistors. In other embodiments, implementations of the third transistor 131, the fourth transistor 132, the transistor 133 and the transistor 134 can be different.

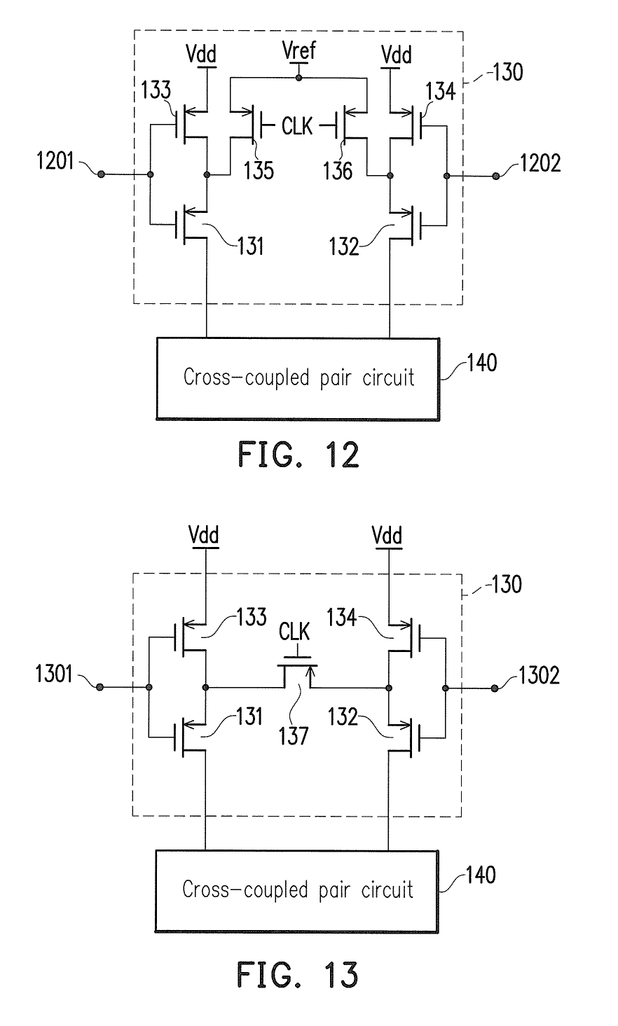

FIG. 12 is a circuit schematic diagram of the second transistor pair circuit 130 of FIG. 3 according to still another embodiment of the disclosure. The embodiment of FIG. 12 can be deduced by referring to related description of FIG. 3, FIG. 4 or FIG. 11. Different to the embodiment of FIG. 11, the second transistor pair circuit 130 of FIG. 12 further includes a switch 135 and a switch 136. Referring to FIG. 12, a node 1201 is coupled to the first terminal of the first current path in the first cross-coupled pair circuit 110, and a node 1202 is coupled to the first terminal of the second current path in the first cross-coupled pair circuit 110. A first terminal (for example, a drain) of the switch 135 is coupled to the second terminal (for example, the source) of the third transistor 131, a control terminal (for example, a gate) of the switch 135 is coupled to a clock signal CLK, and a second terminal (for example, a source) of the switch 135 is coupled to a reference voltage V_{ref} (for example, the system supply voltage Vdd or other bias voltages). A first terminal (for example, a drain) of the switch 136 is coupled to the second terminal (for example, the source) of the fourth transistor 132, a control terminal (for example, a gate) of the switch 136 is coupled to the clock signal CLK, and a second terminal (for example, a source) of the switch 136 is coupled to the reference voltage V_{ref}. When the latch 100 is operated in a reset phase, the switch 135 and the switch 136 are turned on, and voltages at the second terminals of the transistors 131 and 132 are reset to the reference voltage V_{ref}.

FIG. 13 is a circuit schematic diagram of the second transistor pair circuit 130 of FIG. 3 according to yet another embodiment of the disclosure. The embodiment of FIG. 13 can be deduced by referring to related description of FIG. 3, FIG. 4 or FIG. 11. Different to the embodiment of FIG. 11, the second transistor pair circuit 130 of FIG. 13 further includes a switch 137. Referring to FIG. 13, a first terminal (for example, a drain) of the switch 137 is coupled to the second terminal (for example, the source) of the third transistor 131, a second terminal (for example, a source) of the switch 137 is coupled to the second terminal (for example, the source) of the fourth transistor 132, and a control terminal (for example, a gate) of the switch 137 is coupled to the clock signal CLK. When the latch 100 is operated in the reset phase, the switch 137 is turned on, and voltages at the second terminals of the transistors 131 and 132 are averaged. A node 1301 is coupled to the first terminal of the first current path in the first cross-coupled pair circuit 110, and a node 1302 is coupled to the first terminal of the second current path in the first cross-coupled pair circuit 110.

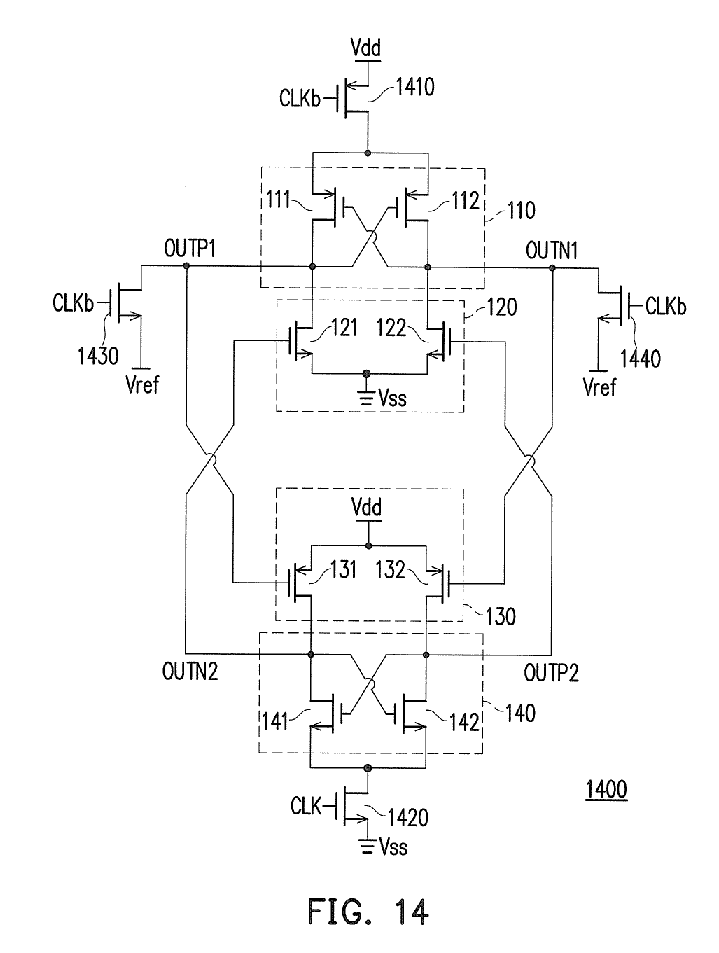

FIG. 14 is a circuit block schematic diagram of a latch 1400 having a clock signal control function according to another embodiment of the disclosure. The embodiment of FIG. 14 can be deduced according to related description of FIG. 3 or FIG. 4. Different to the embodiment of FIG. 4, the latch 1400 of FIG. 14 further includes a switch 1410, a switch 1420, a switch 1430, and a switch 1440, which can all be implemented by transistors. Referring to FIG. 14, a second terminal (for example, a source) of the switch 1410 is coupled to the first power supply voltage (for example, the system supply voltage Vdd), a first terminal (for example, a drain) of the switch 1410 is coupled to the second terminal of the first current path and the second terminal of the second current path in the first cross-coupled pair circuit 110, and a control terminal (for example, a gate) of the switch 1410 is controlled by the clock signal CLKb. A second terminal (for example, a source) of the switch 1420 is coupled to the second power supply voltage (for example, the ground voltage Vss), a first terminal (for example, a drain) of the switch 1420 is coupled to the second terminal of the third current path and the second terminal of the fourth current path in the second cross-coupled pair circuit 140, and a control terminal (for example, a gate) of the switch 1420 is controlled by the clock signal CLK.

A second terminal (for example, a source) of the switch 1430 is coupled to the reference voltage V_{ref} (for example, the ground voltage Vss or other bias voltages), a first terminal (for example, a drain) of the switch 1430 is coupled to the control terminal of the third transistor 131, and a control terminal (for example, a gate) of the switch 1430 is controlled by the clock signal CLKb. A second terminal (for example, a source) of the switch 1440 is coupled to the reference voltage V_{ref}, a first terminal (for example, a drain) of the switch 1440 is coupled to the control terminal of the fourth transistor 132, and a control terminal (for example, a gate) of the switch 1440 is controlled by the clock signal CLKb. When the clock signal CLK has a low voltage, and the clock signal CLKb has a high voltage, the latch 1400 is operated in the reset phase. In the reset phase, the switch 1410 and the switch 1420 (for example, implemented by transistors) are turned off, and the transistors are operated in the cut off region. In the reset phase, the switches 1430 and 1440 (for example, implemented by transistors) are turned on, and the transistors are operated in the triode region. Therefore, the signal OUTP1 and the signal OUTN1 are all pulled down to be close to the reference voltage V_{ref} (for example, the ground voltage Vss). Since the signal OUTP1 and the signal OUTN1 are all pulled down, the third transistor 131 and the fourth transistor 132 are all turned on and operated in the triode region. Meanwhile, the signal OUTP2 and the signal OUTN2 are all pulled up to be close to the system supply voltage V_{dd}. The high voltage signals OUTP2 and OUTN2 may turn on the transistor 121 and the transistor 122, and the transistors 121 and 122 are operated in the triode region. Now, the latch 1400 completes the reset operation.

After the reset operation is completed, the clock signal CLK is transited to the high voltage, and the clock signal CLKb is transited to the low voltage. Now, the latch 1400 is operated in a latch phase. In the latch phase, the switch 1410 and the switch 1420 are turned on, and the switches 1430 and 1440 are turned off. The input signals to be latched are respectively injected to the signal OUTP1 and the signal OUTN1 in a comparison phase, and/or are respectively injected to the signal OUTP2 and the signal OUTN2. Based on the difference of the input signals to be latched, the positive feedback structure of the first cross-latched pair circuit 110 should be able to latch the signal OUTP1 and the signal OUTN1, and the positive feedback structure of the second cross-latched pair circuit 140 is also to latch the signal OUTP2 and the signal OUTN2, so as to implement the latch operation. The latch operation can be deduced by referring to the related description of FIG. 4, which is not repeated.

When the cross-coupled pair circuits 110 and 140 reach a stable state, for example, the signal OUTP1 and the signal OUTP2 should be pulled high to close to the system supply voltage Vdd and the signal OUTN1 and the signal OUTN2 should be pulled low to close to the ground voltage Vss. Since the signal OUTP1 is the system supply voltage Vdd, the transistors 112 and 131 are operated in the cut off region. Namely, the transistor 112 may cut off the static current of the second current path in the stable state, and the third transistor 131 may cut off the static current of the third current path in the stable state. Since the signal OUTN2 is the ground voltage Vss, the transistors 121 and 142 are operated in the cut off region. Namely, the first transistor 121 may cut off the static current of the first current path in the stable state, and the transistor 142 may cut off the static current of the fourth current path in the stable state. Therefore, when the latch 1400 is in the stable state, the static power consumption can be decreased. The latch 1400 can be used in circuits requiring a latch function, for example, a sensing amplifier in internal of a static random access memory (SRAM), a comparator, a flip-flop, . . . , etc.

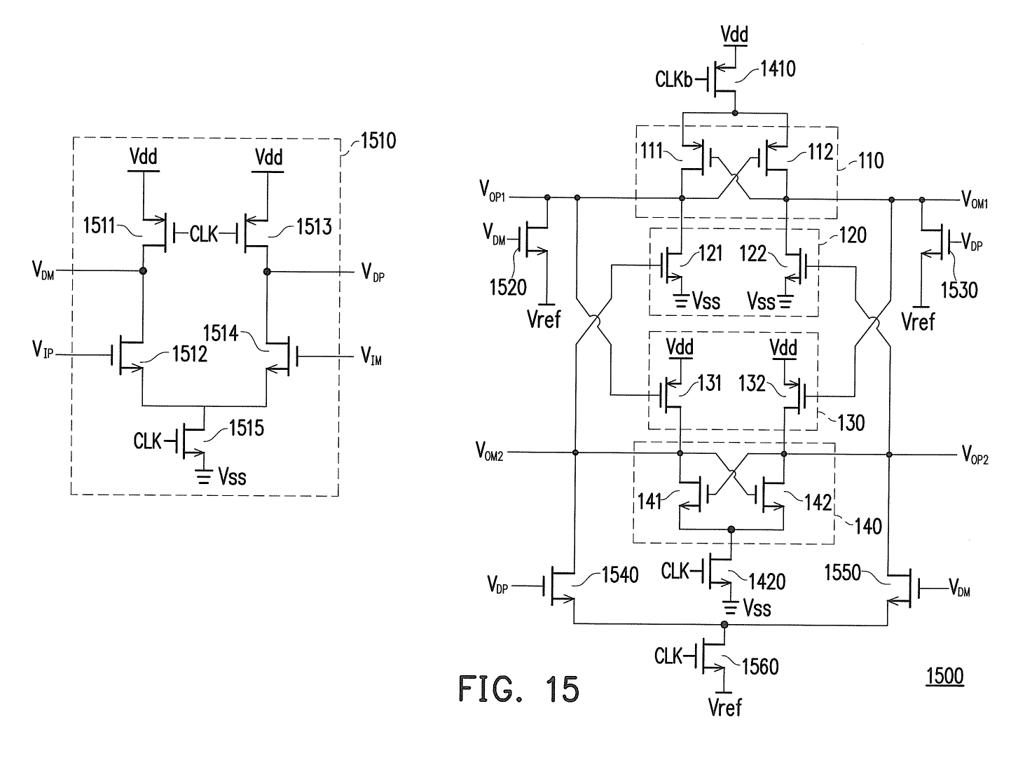

FIG. 15 is a circuit block schematic diagram of a comparator 1500 having a signal comparison function and a process of injecting a latch signal into a latch according to another embodiment of the disclosure. The embodiment of FIG. 15 can be deduced according to related description of FIG. 3, FIG. 4, and FIG. 6 to FIG. 14. Different to the embodiment of FIG. 14, the comparator 1500 of FIG. 15 further includes a dynamic pre-amplifier circuit 1510, and a control circuit, wherein the control circuit comprises a first control circuit, a second control circuit or a third control circuit. The dynamic pre-amplifier circuit 1510 perform a pre-amplifying operation according to a first input signal V_{IP} and a second input signal V_{IM}, and output a first internal signal V_{DM} and a second internal signal V_{DP} to the control circuit. In the present embodiment, the first control circuit includes a switch 1520, a switch 1530, a switch 1540, a switch 1550 and a switch 1560, which can all be implemented by transistor. In another embodiment, the second control circuit includes a switch 1520 and a switch 1530, and switches 1540, 1550 and 1560 in FIG. 15 are removed. In other embodiment, the third control circuit includes a switch 1540, a switch 1550 and a switch 1560, and switches 1520 and 1530 in FIG. 15 are removed.

Referring to FIG. 15, a second terminal (for example, a source) of the switch 1520 is coupled to the reference voltage V_{ref} (for example, the ground voltage Vss or other bias voltages), and a first terminal (for example, a drain) of the switch 1520 is coupled to the control terminal of the third transistor 131. A second terminal (for example, a source) of the switch 1530 is coupled to the reference voltage V_{ref}, and a first terminal (for example, a drain) of the switch 1530 is coupled to the control terminal of the fourth transistor 132. A first terminal (for example, a drain) of the switch 1540 is coupled to the control terminal of the first transistor 121. A first terminal (for example, a drain) of the switch 1550 is coupled to the control terminal of the second transistor 122. A first terminal (for example, a drain) of the switch 1560 is coupled to a second terminal (for example, a source) of the switch 1540 and a second terminal (for example, a source) of the switch 1550, and a second terminal (for example, a source) of the switch 1560 is coupled to the reference voltage V_{ref}.

The dynamic pre-amplifier circuit 1510 performs a pre-amplifying operation according to input signals V_{IP} and V_{IM}, and accordingly outputs a first internal signal V_{DM} to a control terminal of the switch 1520 and a control terminal of the switch 1550, and outputs a second internal signal V_{DP} to a control terminal of the switch 1530 and a control terminal of the switch 1540. In the present embodiment, the dynamic pre-amplifier circuit 1510 includes a transistor 1511, a transistor 1512, a transistor 1513, a transistor 1514 and a transistor 1515. A second terminal (for example, a source) of the transistor 1511 is coupled to the first power supply voltage (for example, the system supply voltage Vdd), a control terminal of the transistor 1511 receives the clock signal CLK, and a first terminal (for example, a drain) of the transistor 1511 is coupled to the control terminal of the switch 1520 and the control terminal of the switch 1550. A first terminal (for example, a drain) of the transistor 1512 is coupled to the first terminal (for example, the drain) of the transistor 1511, and a control terminal of the transistor 1512 receives the first input signal V_{IP}.

A second terminal (for example, a source) of the transistor 1513 is coupled to the first power supply voltage (for example, the system supply voltage Vdd), a control terminal of the transistor 1513 receives the clock signal CLK, and a first terminal (for example, a drain) of the transistor 1513 is coupled to the control terminal of the switch 1530 and the control terminal of the switch 1540. A first terminal (for example, a drain) of the transistor 1514 is coupled to the first tell final (for example, the drain) of the transistor 1513, and a control terminal of the transistor 1514 receives the second input signal V_{IM}. A first terminal (for example, a drain) of the transistor 1515 is coupled to a second terminal (for example, a source) of the transistor 1512 and a second terminal (for example, a source) of the transistor 1514, a control terminal of the transistor 1515 receives the clock signal CLK, and a second terminal of the transistor 1515 is coupled to the second power supply voltage (for example, the ground voltage Vss).

When the clock signal CLK has a low voltage, and the clock signal CLKb has a high voltage, the comparator is operated in the reset phase. In the reset phase, the transistor 1515, the switch 1560, the switch 1410 and the switch 1420 are operated in the cut off region, and the transistor 1511 and the transistor 1513 are operated in the triode region. Therefore, the signal V_{DM} and the signal V_{DP} are all pulled up to be close to the system supply voltage Vdd, and the switch 1520, the switch 1530, the switch 1540 and the switch 1550 are operated in the triode region. Therefore, the signal V_{OP1} and the signal V_{OM1} are all pulled low to be close to the reference voltage V_{ref} (for example, the ground voltage Vss). Namely, the common mode bias of the first cross-coupled pair circuit 110 is operated around the ground voltage Vss other than (Vdd−Vss)/2. Since the signal V_{OP1} and the signal V_{OM1} are all pulled down, the signal V_{OP2} and the signal V_{OM2} are all pulled high to be close to the system supply voltage Vdd. Namely, the common mode bias of the second cross-coupled pair circuit 140 is operated around the system supply voltage Vdd other than (Vdd−Vss)/2. Now, the comparator 1500 completes the reset operation, and the reset operation may refer to related description of FIG. 14, which is not repeated.

After the reset operation is completed, the clock signal CLK is transited to the high voltage, and the clock signal CLKb is transited to the low voltage. Now, the comparator 1500 is operated in a comparison phase. In the comparison phase, the transistor 1515, the switch 1560, the switch 1410 and the switch 1420 are turned on and gradually enter the triode region, and the transistor 1511, the transistor 1513 are operated in the cut off region. In the comparison phase, a difference of the input signals V_{IP} and V_{IM} make the transistor 1512 and the transistor 1514 having different discharging speeds. Therefore, in the comparison phase, the signal V_{DP} and the signal V_{DM} also has a difference. Based on the difference between the signal V_{DP} and the signal V_{DM}, the positive feedback path of the first cross-coupled pair circuit 110 should be able to latch the signal V_{OP1} and the signal V_{OM1}, and the positive feedback path of the second cross-coupled pair circuit 140 is also to latch the signal V_{OP2} and the signal V_{OM2}, so as to perform the latch/comparison operation. The latch/comparison operation can be deduced by referring to the related description of FIG. 4, which is not repeated. When the cross-coupled pair circuits 110 and 140 reach the stable state, according to the related description of FIG. 14, the static currents of the first current path, the second current path, the third current path, and the fourth current path are almost zero. Therefore, when the comparator 1500 is in the stable state, the static power consumption of the comparator 1500 can be decreased.

In the comparator 1500, the voltage of at least one of the first terminal of the first current path of the first cross-coupled pair circuit 110, the first terminal of the second current path of the first cross-coupled pair circuit 110, the first terminal of the third current path of the second cross-coupled pair circuit 140, and the first terminal of the fourth current path of the second cross-coupled pair circuit 140 may serve as a comparison result of the comparator 1500. In another embodiment, the comparator 1500 can be further configured with an output stage circuit for outputting the comparison result of the comparator 1500. A first input terminal, a second input terminal, a third input terminal and a fourth input terminal of the output stage circuit are respectively coupled to the first terminal of the first current path of the first cross-coupled pair circuit 110, the first terminal of the second current path of the first cross-coupled pair circuit 110, the first terminal of the third current path of the second cross-coupled pair circuit 140 and the first terminal of the fourth current path of the second cross-coupled pair circuit 140 for respectively receiving the signal V_{OP1}, the signal V_{OM1}, the signal V_{OP2} and the signal V_{OM2}. The output stage circuit correspondingly outputs the comparison result of the comparator 1500 according to the first, second, third, and fourth input terminals.

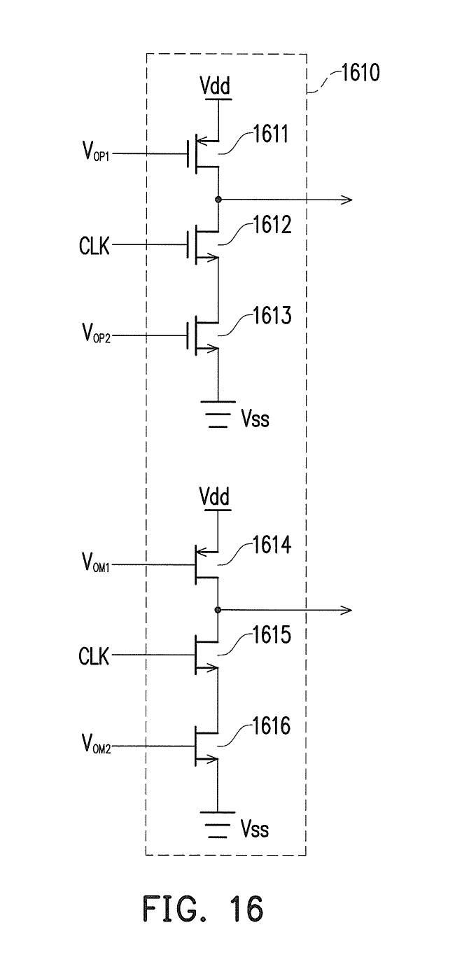

FIG. 16 is a schematic diagram of an output signal readout circuit 1610 of the comparator 1500 of FIG. 15 according to an embodiment of the disclosure. The output stage circuit 1610 includes a transistor 1611, a transistor 1612, a transistor 1613, a transistor 1614, a transistor 1615 and a transistor 1616. A second terminal (for example, a source) of the transistor 1611 is coupled to the first power supply voltage (for example, the system supply voltage Vdd). A control terminal (for example, a gate) of the transistor 1611 serves as a first input terminal of the output stage circuit 1610 for receiving the signal V_{OP1} in FIG. 15. A first terminal (for example, a drain) of the transistor 1611 may serve as a first output terminal of the output stage circuit 1610. A first terminal (for example, a drain) of the transistor 1612 is coupled to the first terminal of the transistor 1611. A control terminal (for example, a gate) of the transistor 1612 receives the clock signal CLK. A first terminal (for example, a drain) of the transistor 1613 is coupled to a second terminal (for example, a source) of the transistor 1612. A control terminal (for example, a gate) of the transistor 1613 serves as a second input terminal of the output stage circuit 1610 for receiving the signal V_{OP2} in FIG. 15. A second terminal (for example, a source) of the transistor 1613 is coupled to the second power supply voltage (for example, the ground voltage Vss).

A second terminal (for example, a source) of the transistor 1614 is coupled to the first power supply voltage. A control terminal (for example, a gate) of the transistor 1614 serves as a third input terminal of the output stage circuit 1610 for receiving the signal V_{OM1} in FIG. 15. A first terminal (for example, a drain) of the transistor 1614 serves as a second output terminal of the output stage circuit 1610. A first terminal (for example, a drain) of the transistor 1615 is coupled to the first terminal of the transistor 1614. A control terminal (for example, a gate) of the transistor 1615 receives the clock signal CLK. A first terminal (for example, a drain) of the transistor 1616 is coupled to a second terminal (for example, a source) of the transistor 1615. A control terminal (for example, a gate) of the transistor 1616 serves as a fourth input terminal of the output stage circuit 1610 for receiving the signal V_{OM2} in FIG. 15. A second terminal (for example, a source) of the transistor 1616 is coupled to the second power supply voltage.

In summary, the latch of the disclosure can be operated under a low supply voltage, and has characteristics of high speed, high amplification gain, low deviation, low power consumption, etc. The latch can be applied in circuits requiring the latch function, for example, a sensing amplifier in internal of a static random access memory (SRAM), a comparator, a flip-flop, . . . , etc.

It will be apparent to those skilled in the art that various modifications and variations can be made to the structure of the disclosure without departing from the scope or spirit of the disclosure. In view of the foregoing, it is intended that the disclosure cover modifications and variations of this disclosure provided they fall within the scope of the following claims and their equivalents.

1. A latch, comprising:
a first cross-coupled pair circuit, comprising a first current path and a second current path, wherein a control terminal of the first current path is coupled to the second current path, and a control terminal of the second current path is coupled to the first current path;
a first transistor pair circuit, comprising a first transistor and a second transistor, wherein a first terminal of the first transistor is coupled to a first terminal of the first current path, and a first terminal of the second transistor is coupled to a first terminal of the second current path;
a second transistor pair circuit, comprising a third transistor and a fourth transistor, wherein a control terminal of the third transistor is coupled to the first current path of the first cross-coupled pair circuit, and a control terminal of the fourth transistor is coupled to the second current path of the first cross-coupled pair circuit; and
a second cross-coupled pair circuit, comprising a third current path and a fourth current path, wherein a control terminal of the third current path is coupled to the fourth current path, a control terminal of the fourth current path is coupled to the third current path, a first terminal of the third current path is coupled to a first terminal of the third transistor, a first terminal of the fourth current path is coupled to a first terminal of the fourth transistor, a control terminal of the first transistor is coupled to the third current path, and a control terminal of the second transistor is coupled to the fourth current path.

2. The latch as claimed in claim 1, wherein the first cross-coupled pair circuit and the second transistor pair circuit are a first conductive type, and the first transistor pair circuit and the second cross-coupled pair circuit are a second conductive type.

3. The latch as claimed in claim 1, wherein the first cross-coupled pair circuit comprises:
a fifth transistor, configured in the first current path, wherein a first terminal of the fifth transistor servers as the first terminal of the first current path, and a control terminal of the fifth transistor serves as the control terminal of the first current path; and
a sixth transistor, configured in the second current path, wherein a first terminal of the sixth transistor serves as the first terminal of the second current path and is coupled to the control terminal of the fifth transistor, and a control terminal of the sixth transistor serves as the control terminal of the second current path and is coupled to the first terminal of the fifth transistor.

4. The latch as claimed in claim 3, wherein the first cross-coupled pair circuit further comprises:
a first impedance, having a first terminal coupled to a second terminal of the fifth transistor; and
a second impedance, having a first terminal coupled to a second terminal of the sixth transistor.

5. The latch as claimed in claim 1, wherein the second cross-coupled pair circuit comprises:
a fifth transistor, configured in the third current path, wherein a first terminal of the fifth transistor servers as the first terminal of the third current path, and a control terminal of the fifth transistor serves as the control terminal of the third current path; and
a sixth transistor, configured in the fourth current path, wherein a first terminal of the sixth transistor serves as the first terminal of the fourth current path and is coupled to the control terminal of the fifth transistor, and a control terminal of the sixth transistor serves as the control terminal of the fourth current path and is coupled to the first terminal of the fifth transistor.

6. The latch as claimed in claim 5, wherein the second cross-coupled pair circuit further comprises:
a first impedance, having a first terminal coupled to a second terminal of the fifth transistor; and
a second impedance, having a first terminal coupled to a second terminal of the sixth transistor.

7. The latch as claimed in claim 1, wherein a second terminal of the third transistor and a second terminal of the fourth transistor are coupled to a first power supply voltage, and a second terminal of the first transistor and a second terminal of the second transistor are coupled to a second power supply voltage.

8. The latch as claimed in claim 1, wherein the first transistor pair circuit further comprises:
a fifth transistor, having a first terminal coupled to a second terminal of the first transistor, and a control terminal coupled to the control terminal of the first transistor; and
a sixth transistor, having a first terminal coupled to a second terminal of the second transistor, and a control terminal coupled to the control terminal of the second transistor.

9. The latch as claimed in claim 8, wherein the first transistor pair circuit further comprises:
a first switch, having a first terminal coupled to the second terminal of the first transistor, a control terminal coupled to a clock signal, and a second terminal coupled to a reference voltage; and
a second switch, having a first terminal coupled to the second terminal of the second transistor, a control terminal coupled to the clock signal, and a second terminal coupled to the reference voltage.

10. The latch as claimed in claim 8, wherein the first transistor pair circuit further comprises:
a switch, having a first terminal coupled to the second terminal of the first transistor, a second terminal coupled to the second terminal of the second transistor, and a control terminal coupled to a clock signal.

11. The latch as claimed in claim 1, wherein the second transistor pair circuit further comprises:
a fifth transistor, having a first terminal coupled to a second terminal of the third transistor, and a control terminal coupled to the control terminal of the third transistor; and
a sixth transistor, having a first terminal coupled to a second terminal of the fourth transistor, and a control terminal coupled to the control terminal of the fourth transistor.

12. The latch as claimed in claim 11, wherein the second transistor pair circuit further comprises:
a first switch, having a first terminal coupled to the second terminal of the third transistor, a control terminal coupled to a clock signal, and a second terminal coupled to a reference voltage; and
a second switch, having a first terminal coupled to the second terminal of the fourth transistor, a control terminal coupled to the clock signal, and a second terminal coupled to the reference voltage.

13. The latch as claimed in claim 11, wherein the second transistor pair circuit further comprises:
a switch, having a first terminal coupled to the second terminal of the third transistor, a second terminal coupled to the second terminal of the fourth transistor, and a control terminal coupled to a clock signal.

14. The latch as claimed in claim 1, wherein a second terminal of the first current path and a second terminal of the second current path are coupled to a first power supply voltage, and a second terminal of the third current path and a second terminal of the fourth current path are coupled to a second power supply voltage.

15. The latch as claimed in claim 1, further comprising:
a first switch, having a first terminal coupled to a second terminal of the first current path and a second terminal of the second current path, and having a second terminal coupled to a first power supply voltage; and
a second switch, having a first terminal coupled to a second terminal of the third current path and a second terminal of the fourth current path, and having a second terminal coupled to a second power supply voltage.

16. The latch as claimed in claim 1, further comprising:
a first switch, having a first terminal coupled to the control terminal of the third transistor, and a second terminal coupled to a reference voltage; and
a second switch, having a first terminal coupled to the control terminal of the fourth transistor, and a second terminal coupled to the reference voltage.

17. The latch as claimed in claim 16, further comprising:
a third switch, having a first terminal coupled to the control terminal of the first transistor;
a fourth switch, having a first terminal coupled to the control terminal of the second transistor; and
a fifth switch, having a first terminal coupled to a second terminal of the third switch and a second terminal of the fourth switch, and having a second terminal coupled to the reference voltage.

18. The latch as claimed in claim 17, further comprising:
a sixth switch, having a first terminal coupled to a second terminal of the first current path and a second terminal of the second current path, and having a second coupled to a first power supply voltage; and
a seventh switch, having a first terminal coupled to a second terminal of the third current path and a second terminal of the fourth current path, and having a second terminal coupled to a second power supply voltage.

19. The latch as claimed in claim 16, further comprising:
a dynamic pre-amplifier circuit, performing a pre-amplifying operation according to a first input signal and a second input signal for correspondingly outputting a first internal signal to a control terminal of the second switch and a control terminal of the third switch, and correspondingly outputting a second internal signal to a control terminal of the first switch and a control terminal of the fourth switch.

20. The latch as claimed in claim 19, wherein the dynamic pre-amplifier circuit comprises:
a fifth transistor, having a control terminal receiving a clock signal;
a sixth transistor, having a first terminal coupled to a first terminal of the fifth transistor, and a control terminal of the sixth transistor receiving the first input signal, wherein a second terminal of the fifth transistor is coupled to a first power supply voltage;
a seventh transistor, having a control terminal receiving the clock signal;
an eighth transistor, having a first terminal coupled to a first terminal of the seventh transistor, and a control terminal of the eighth transistor receiving the second input signal, wherein a second terminal of the seventh transistor is coupled to the first power supply voltage; and
a ninth transistor, having a first terminal coupled to a second terminal of the sixth transistor and a second terminal of the eighth transistor, a control terminal receiving the clock signal, and a second terminal coupled to a second power supply voltage.

21. The latch as claimed in claim 1, wherein a voltage in at least one of the first current path, the second current path, the third current path and the fourth current path serves as a comparison result of the latch.

22. The latch as claimed in claim 1, further comprising:
an output stage circuit, having a first input terminal, a second input terminal, a third input terminal and a fourth input terminal respectively coupled to the first current path, the fourth current path, the second current path and the third current path, wherein the output stage circuit correspondingly outputs a comparison result of the latch according to the first input terminal, the second input terminal, the third input terminal and the fourth input terminal.

23. The latch as claimed in claim 22, wherein the output stage circuit comprises:
a fifth transistor, having a control terminal coupled to the first input terminal of the output stage circuit;
a sixth transistor, having a first terminal coupled to a first terminal of the fifth transistor, and a control terminal of the sixth transistor receiving a clock signal, wherein a second terminal of the fifth transistor is coupled to a first power supply voltage;
a seventh transistor, having a first terminal coupled to a second terminal of the sixth transistor, a control terminal coupled to the second input terminal of the output stage circuit, and a second terminal coupled to a second power supply voltage;
an eighth transistor, having a control terminal coupled to the third input terminal of the output stage circuit;
a ninth transistor, having a first terminal coupled to a first terminal of the eighth transistor, and a control terminal of the ninth transistor receiving the clock signal, wherein a second terminal of the eighth transistor is coupled to the first power supply voltage; and
a tenth transistor, having a first terminal coupled to a second terminal of the ninth transistor, a control terminal coupled to the fourth input terminal of the output stage circuit, and a second terminal coupled to the second power supply voltage.

24. An operation method of a latch, comprising:
configuring a first cross-coupled pair circuit, wherein the first cross-coupled pair circuit comprises a first current path and a second current path, a control terminal of the first current path is coupled to the second current path, and a control terminal of the second current path is coupled to the first current path;
configuring a first transistor pair circuit, wherein the first transistor pair circuit comprises a first transistor and a second transistor, a first terminal of the first transistor is coupled to a first terminal of the first current path, and a first terminal of the second transistor is coupled to a first terminal of the second current path;
configuring a second transistor pair circuit, wherein the second transistor pair circuit comprises a third transistor and a fourth transistor, a control terminal of the third transistor is coupled to the first current path of the first cross-coupled pair circuit, and a control terminal of the fourth transistor is coupled to the second current path of the first cross-coupled pair circuit;
configuring a second cross-coupled pair circuit, wherein the second cross-coupled pair circuit comprises a third current path and a fourth current path, a control terminal of the third current path is coupled to the fourth current path, a control terminal of the fourth current path is coupled to the third current path, a first terminal of the third current path is coupled to a first terminal of the third transistor, a first terminal of the fourth current path is coupled to a first terminal of the fourth transistor, a control terminal of the first transistor is coupled to the third current path, and a control terminal of the second transistor is coupled to the fourth current path;
in a signal transition phase, injecting an input signal into the first current path, the second current path, the third current path or the fourth current path, and amplifying the injected input signal by the first cross-coupled pair circuit and the second cross-coupled pair circuit; and
in a stable phase, cutting off a static current of the first current path or the second current path by the first transistor pair circuit, and cutting off a static current of the third current path or the fourth current path by the second transistor pair circuit.

25. A comparator, comprising:
a first cross-coupled pair circuit, comprising a first current path and a second current path, wherein a control terminal of the first current path is coupled to the second current path, and a control terminal of the second current path is coupled to the first current path;
a first transistor pair circuit, comprising a first transistor and a second transistor, wherein a first terminal of the first transistor is coupled to a first terminal of the first current path, and a first terminal of the second transistor is coupled to a first terminal of the second current path;
a second transistor pair circuit, comprising a third transistor and a fourth transistor, wherein a control terminal of the third transistor is coupled to the first current path of the first cross-coupled pair circuit, and a control terminal of the fourth transistor is coupled to the second current path of the first cross-coupled pair circuit;
a second cross-coupled pair circuit, comprising a third current path and a fourth current path, wherein a control terminal of the third current path is coupled to the fourth current path, a control terminal of the fourth current path is coupled to the third current path, a first terminal of the third current path is coupled to a first terminal of the third transistor, a first terminal of the fourth current path is coupled to a first terminal of the fourth transistor, a control terminal of the first transistor is coupled to the third current path, and a control terminal of the second transistor is coupled to the fourth current path;
a first switch, having a first terminal coupled to a second terminal of the first current path and a second terminal of the second current path, and having a second terminal coupled to a first power supply voltage;
a second switch, having a first terminal coupled to a second terminal of the third current path and a second terminal of the fourth current path, and having a second terminal coupled to a second power supply voltage;
a control circuit comprising a first control circuit, a second control circuit or a third control circuit; and
a dynamic pre-amplifier circuit, performing a pre-amplifying operation according to a first input signal and a second input signal, and outputting a first internal signal and a second internal signal to the control circuit;
wherein the first control circuit comprises a third switch, a fourth switch, a fifth switch, a sixth switch and a seventh switch, a first terminal of the third switch coupled to the control terminal of the third transistor, a second terminal of the third switch coupled to a reference voltage, a first terminal of the fourth switch coupled to the control terminal of the fourth transistor, a second terminal of the fourth switch coupled to the reference voltage, a first terminal of the fifth switch coupled to the control terminal of the first transistor, a first terminal of the sixth switch coupled to the control terminal of the second transistor, a first terminal of the seventh switch coupled to a second terminal of the fifth switch and a second terminal of the sixth switch, a second terminal of the seventh switch coupled to the reference voltage, the dynamic pre-amplifier circuit outputs the first internal signal to the control terminal of the fourth switch and the control terminal of the fifth switch, and the dynamic pre-amplifier circuit outputs a second internal signal to the control terminal of the third switch and the control terminal of the sixth switch;
wherein the second control circuit comprises a third switch and a fourth switch, a first terminal of the third switch coupled to the control terminal of the third transistor, a second terminal of the third switch coupled to a reference voltage, a first terminal of the fourth switch coupled to the control terminal of the fourth transistor, a second terminal of the fourth switch coupled to the reference voltage, the dynamic pre-amplifier circuit outputs the first internal signal to the control terminal of the fourth switch, and the dynamic pre-amplifier circuit outputs the second internal signal to the control terminal of the third switch; and
wherein the third control circuit comprises a fifth switch, a sixth switch and a seventh switch, a first terminal of the fifth switch coupled to the control terminal of the first transistor, a first terminal of the sixth switch coupled to the control terminal of the second transistor, a first terminal of the seventh switch coupled to a second terminal of the fifth switch and a second terminal of the sixth switch, a second terminal of the seventh switch coupled to the reference voltage, the dynamic pre-amplifier circuit outputs the first internal signal to the control terminal of the fifth switch, and the dynamic pre-amplifier circuit outputs the second internal signal to the control terminal of the sixth switch.
